(19) United States
(12) Patent Application Publication
(10) Pub. No.: US 2019/0178904 A1
(43) Pub. Date: Jun. 13, 2019

(54) DEVICE, SYSTEM AND METHOD FOR STRESS-SENSITIVE COMPONENT ISOLATION IN SEVERE ENVIRONMENTS

(71) Applicant: Honeywell International Inc., Morris Plains, NJ (US)

(72) Inventors: Todd Loren Braman, New Brighton, MN (US); Timothy J. Hanson, Plymouth, MN (US); Terrance Troske, White Bear Lake, MN (US)

(21) Appl. No.: 15/837,766

(22) Filed: Dec. 11, 2017

(51) Int. Cl. G01P 1/02; H05K 7/14; H05K 1/14; H05K 1/18; G01C 21/16; F16F 15/08

(52) U.S. Cl. CPC G01P 1/023; H05K 7/1434; F16F 15/08; H05K 1/189; G01C 21/16; H05K 1/147

(57) ABSTRACT

A system, device and method for stress-sensitive component isolation in severe environments are disclosed. For example, a device for stress-sensitive component isolation is disclosed, which includes a circuit board assembly, a plurality of electronic components mounted onto a surface of the circuit board assembly, and a protective cap disposed over at least one electronic component and mounted onto the surface of the circuit board assembly. The protective cap can be filled with a low modulus material if additional structural support is desired for the electronic component.

### BACKGROUND

Inertial Measurement Units (IMUs) are devices that can sense the rotation and acceleration of an object. For example, IMUs can be utilized to detect the rate of acceleration and the change in rotational attributes of objects about three axes for a given period of time. In space applications, IMUs are utilized in navigational and guidance systems for launch vehicles, spacecraft, satellites and the like. In other applications, IMUs are utilized to guide (e.g., gun-launched) large caliber projectiles. Notably, during the launch of a spacecraft, satellite or large caliber projectile, the electronic components in the onboard IMUs are subjected to the high temperatures, high shock loads and high vibration levels (e.g., referred to herein as “severe environments”) caused by the high acceleration and g-force levels involved.

Cavity potting is one process utilized to encapsulate and support electronic components (e.g., components mounted on a printed board assembly or PBA) by placing a component in a container, filling a cavity between the container and the component with a suitable potting material (e.g., a resin), and curing the material to form an integral potted component. However, when cavity potting is utilized to encapsulate electronic components in order to meet the stringent system requirements imposed for severe environments encountered, for example, during high g-force gun launches, the potting materials utilized to support the electronic components can induce high levels of stress on the potted components during the life of the device.

Designers typically attempt to minimize this stress by selecting more flexible (e.g., lower elastic modulus) potting materials and/or utilizing potting materials having matching coefficients of thermal expansion (CTEs). However, as the severity of an environment is increased (e.g., higher g-forces, temperatures, shock loads, vibrations, etc.), the selection of suitable potting materials becomes more limited because these materials are required to support the higher loads. Consequently, the potting materials needed to support these higher loads must be less flexible (e.g., higher elastic modulus), which can induce additional stress into the encapsulated components involved.

In summary, fewer potting materials have become available for electronic component encapsulation as the severities of the operating environments have increased. Consequently, the conventional practice of attempting to match the CTEs of such a limited number of potting materials has become more challenging, and has resulted in non-optimal design conditions in which additional stress can be induced into the electronic components involved.

For the reasons stated above, and for other reasons stated below, which will become apparent to those skilled in the art upon reading and understanding the specification, there is a need in the art for a way to isolate stress-sensitive electronic components from stresses induced by high modulus potting materials utilized in severe environments.

### SUMMARY

The embodiments of the present invention provide ways to isolate stress-sensitive components from higher modulus potting materials utilized in severe environments, and will be understood by reading and studying the following specification.

A device, system and method for stress-sensitive component isolation in severe environments are provided. For example, a device for stress-sensitive component isolation is disclosed. The device includes a circuit board assembly, a plurality of electronic components mounted onto a surface of the circuit board assembly, and a protective cap disposed over at least one electronic component of the plurality of electronic components and mounted onto the surface of the circuit board assembly. As such, the protective cap isolates the stress-sensitive electronic component from stresses induced by higher modulus potting materials utilized to encapsulate and support the electronic components throughout the life of the device.

### DRAWINGS

Embodiments of the present invention can be more easily understood and further advantages and uses thereof more readily apparent, when considered in view of the description of the preferred embodiments and the following figures in which:

FIGS. 1A-1D are related structural diagrams illustrating perspective views of a device that can be utilized to implement one example embodiment of the present invention.

FIGS. 2A-2B are related, structural diagrams illustrating cross-sectional, side views of the device depicted in FIG. 1C.

FIGS. 3A-3B are related, structural diagrams illustrating cross-sectional, side views of the device depicted in FIG. 1D.

FIG. 4 illustrates a method that can be utilized to implement one example embodiment of the present invention.

FIG. 5 illustrates a system that can be utilized to implement one example embodiment of the present invention.

In accordance with common practice, the various described features are not drawn to scale but are drawn to emphasize specific features relevant to the exemplary embodiments. Reference characters denote like elements throughout the figures and text.

### DETAILED DESCRIPTION

In the following detailed description, reference is made to the accompanying drawings that form a part hereof, and in which is shown by way of specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. The following detailed description is, therefore, not to be taken in a limiting sense.

Embodiments of the present invention improve on the prior art by utilizing a cavity potting process that enables any electronic component that would be adversely affected by the potting material to be isolated from that material. In one example embodiment, a protective cap (or cover) is placed over an electronic component to isolate the component from a high modulus potting material to be utilized. In a second example embodiment, a second potting material having a lower elastic modulus than that of the first potting material (e.g., in order to match the two materials' CTEs) is utilized to fill the cavity between the protective cap and the electronic component involved. As such, in accordance with the teachings of the present disclosure, higher modulus potting materials can be utilized to support electronic components that are less sensitive to stress, and electronic components that are more sensitive to stress can be isolated from the higher modulus potting material by the protective cap utilized. Furthermore, if such an isolated stress-sensitive component requires additional support, for example, in order to meet more stringent mission requirements, the cavity between the protective cap and the component can be filled with a lower modulus, less stress-inducing potting material to provide the additional support required. Thus, in accordance with the teachings of the present disclosure, stress-sensitive components can be isolated from stress-inducing potting materials and thereby enabled to withstand the severe environments encountered during a launch.

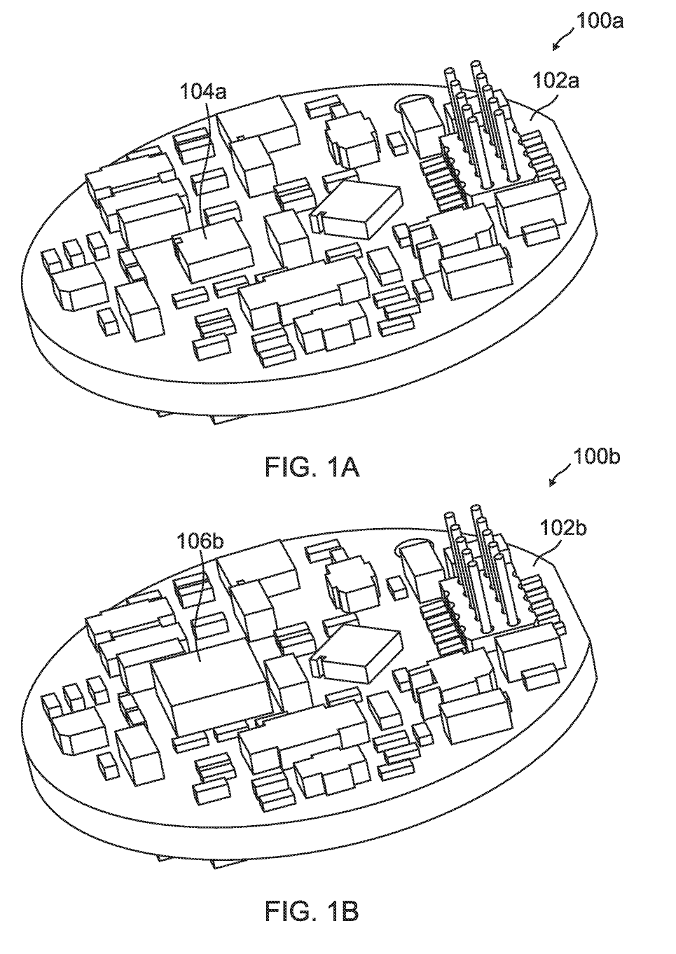

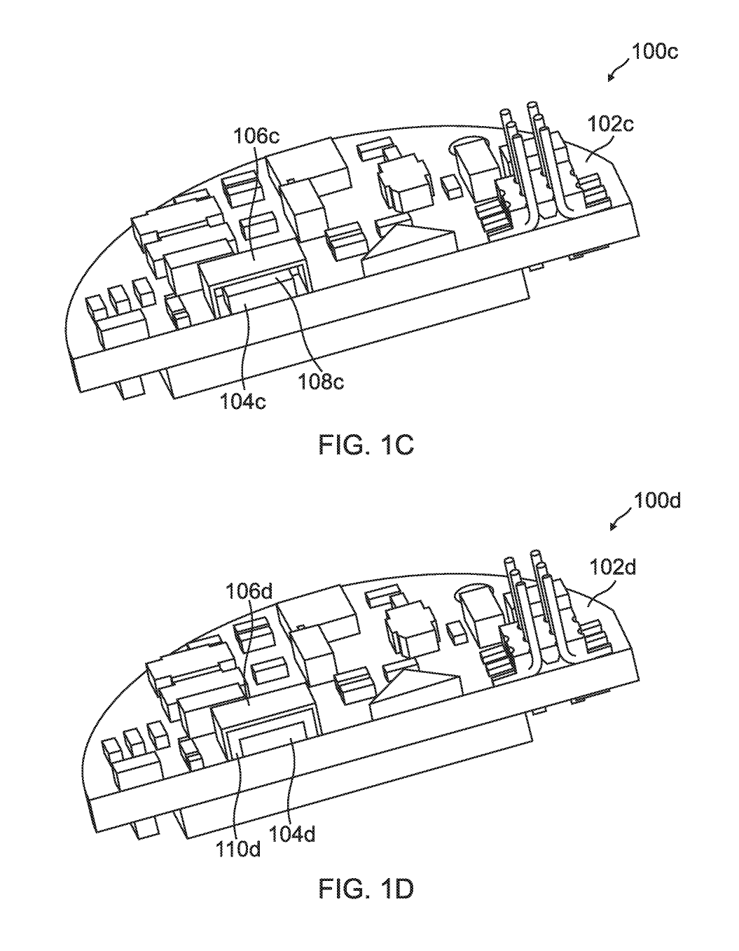

FIGS. 1A-1D are related structural diagrams illustrating perspective views of a device 100a-100d, which can be utilized to implement one example embodiment of the present invention. Referring to FIG. 1A, the device 100a includes a PBA 102a. Notably, although the PBA 102a is shown in the embodiment illustrated in FIG. 1A, any suitable device (e.g., printed circuit, printed wire assembly or PWA, and the like) that can provide a base for mounting and encapsulating one or more electronic components can be utilized. The device 100a also includes an electronic component 104a mounted onto the upper surface of the PBA 102a (e.g., utilizing a known component mounting and soldering process). Notably, in one embodiment, in an IMU and/or guidance system, the electronic component 104a can be a Micro-Electro-Mechanical Systems (MEMS) component mounted on the upper surface of the PBA 102a. For example, the electronic component 104a can be one sensor of a plurality of MEMS sensors mounted on the PBA 102a. As such, in one embodiment, the electronic component 104a can be, for example, a rate sensor, accelerometer, or oscillator mounted on the PBA 102a in an enclosure within an IMU. However, although a sensor is contemplated to implement the electronic component 104a in one embodiment, in a different embodiment, any electronic component having a suitable functional capability can be utilized to implement the electronic component 104a.

Referring to FIG. 1B, the device 100b further includes a protective cap (or cover) 106b disposed over the electronic component (e.g., 104a in FIG. 1A) and mounted onto the upper surface of the PBA 102b. For example, in one embodiment, the protective cap 106b can be made of a suitable material (e.g., an epoxy, an encapsulating material and the like) that is capable of withstanding the extreme conditions (e.g., heat, shock, vibration, stress) encountered in the severe environment created during a launch. In a second embodiment, the protective cap 106b can be, for example, a container that can form a suitable cavity for use in a cavity potting process.

Referring to FIG. 1C, a cross-sectional, side view of the device 100b illustrated in FIG. 1B is depicted. As such, the example embodiment illustrated in FIGS. 1B and 1C includes a cavity 108c, which is formed by the open space between the protective cap 106c and the electronic component 104c, which are both mounted onto the upper surface of the PBA 102c. Accordingly, the protective cap 106c and the cavity 108c function to isolate and thereby protect the (e.g., stress-sensitive) electronic component 104c from the launch-induced stresses created by the high modulus potting material utilized to encapsulate the PBA 102c.

Referring to FIG. 1D, a second, cross-sectional, side view of the device 100b illustrated in FIG. 1B is depicted. For this example embodiment, the device 100d includes an electronic component 104d and a protective cap 106d, which are both mounted onto the upper surface of the PBA 102d. However, for this embodiment, additional support is desired to strengthen the electronic component 104c (e.g., in order to meet more stringent mission requirements). Consequently, in order to provide the additional support desired, the cavity 108c depicted in FIG. 1C is filled with a suitable potting material 110d (as depicted in FIG. 1D), or, for example, in a second embodiment, the filler material utilized can be an expandable polystyrene bead foam. As such, for this embodiment, the cavity 108c depicted in FIG. 1C is filled with a lower modulus, less stress-inducing material 110d to provide the additional support required without substantially increasing the stress on the electronic component 104d throughout the life of the device.

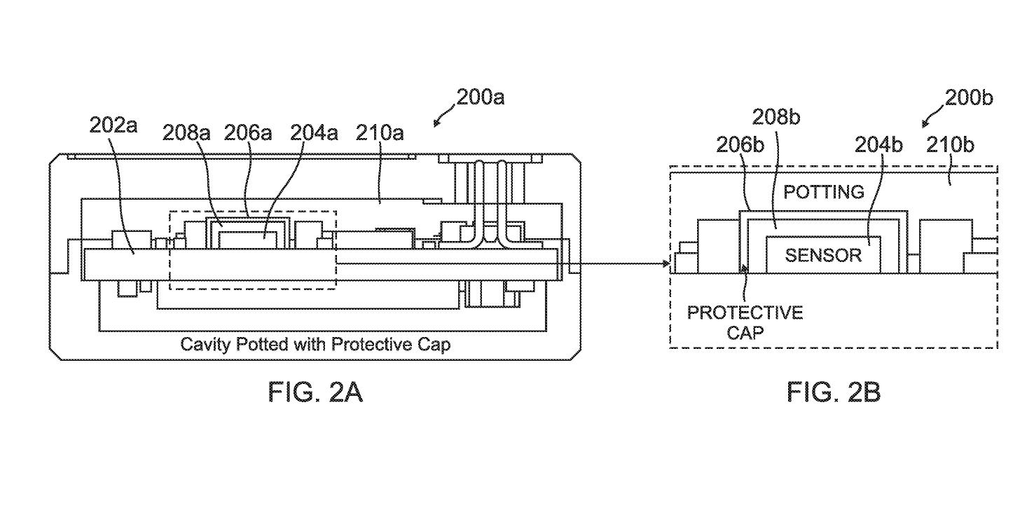

FIGS. 2A-2B are related, structural diagrams illustrating cross-sectional, side views of the device 100c depicted in FIG. 1C. However, the example embodiment illustrated in FIGS. 2A-2B depicts the entire device 200a, 200b encapsulated with a suitable (e.g., high modulus of elasticity) potting material 210a, 210b. Referring to FIG. 2A, the device 200a includes a PBA 202a. An electronic component 204a is shown mounted onto the upper surface of the PBA 202a, and a protective cap 206a is disposed over the electronic component 204a and also mounted onto the upper surface of the PBA 202a (e.g., utilizing a known component mounting and soldering process). Thus, a cavity 208a is formed by the space between the electronic component 204a and the protective cap 206a. Referring to the expanded view depicted in FIG. 2B, for this example embodiment, the electronic component 204b is a sensor (e.g., a MEMS sensor, rate sensor, accelerometer or oscillator), and the protective cap 206b, cavity 208b, and sensor 204b are encapsulated with the (e.g., high modulus) potting material 210b.

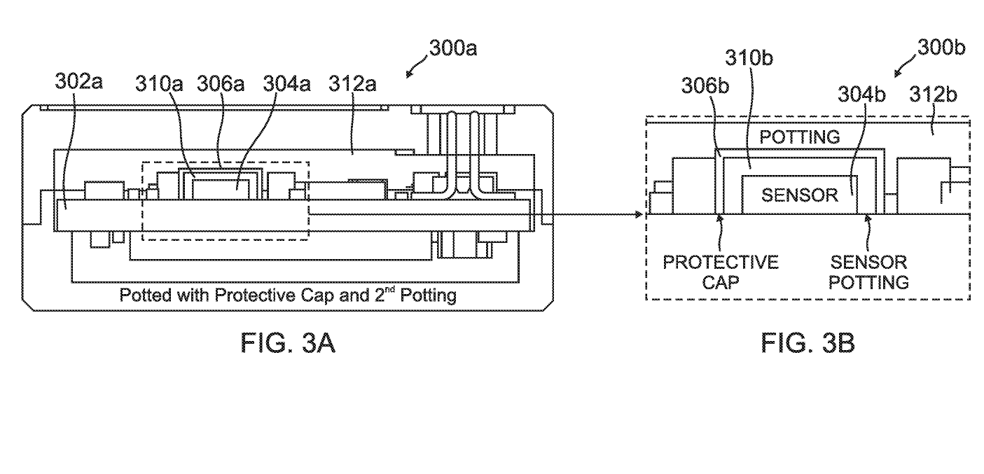

FIGS. 3A-3B are related, structural diagrams illustrating cross-sectional, side views of the device 100d depicted in FIG. 1D. However, the example embodiment depicted in FIGS. 3A-3B depicts the cavity (208a and 208b in FIGS. 2A, 2B) filled with a suitable (e.g., low modulus of elasticity) potting material 310a, 310b. Also, the entire device 300a is encapsulated with a suitable (e.g., high modulus) potting material 312a, 312b. Referring to FIG. 3A, the device 300a includes a PBA 302a. An electronic component 304a is shown mounted onto the upper surface of the PBA 302a, and a protective cap 306a is disposed over the electronic component 304a and also mounted onto the upper surface of the PBA 302a. Referring to the expanded view depicted in FIG. 3B, for this example embodiment, the electronic component 304b is a sensor (e.g., a MEMS sensor, rate sensor, accelerometer or oscillator), and the protective cap 306b, filled cavity 310b, and sensor 304b are encapsulated with the (e.g., high modulus) potting material 312b.

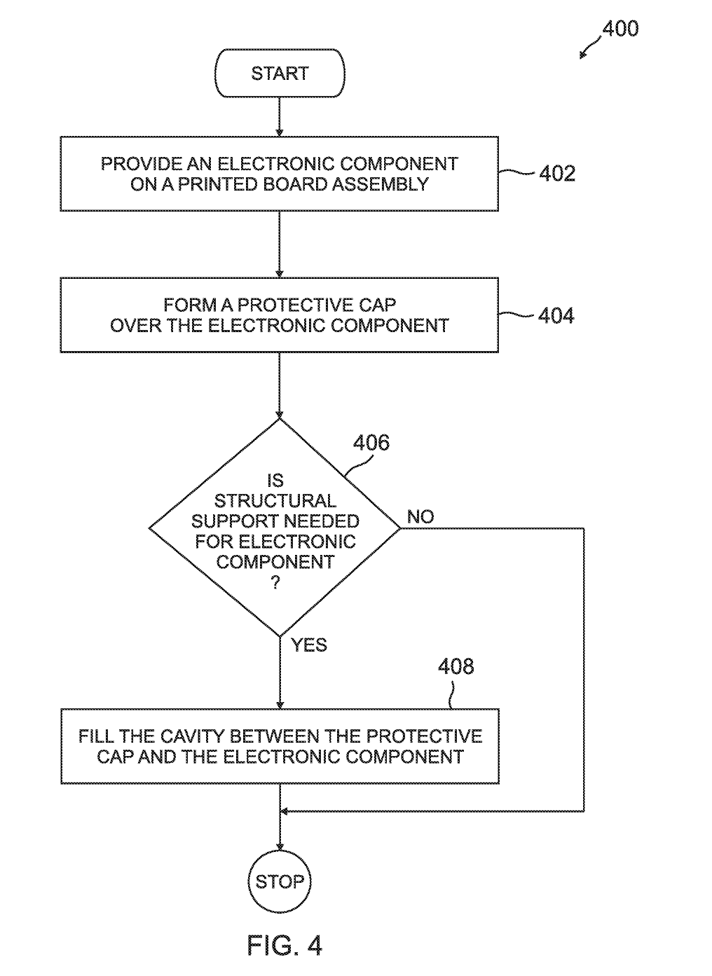

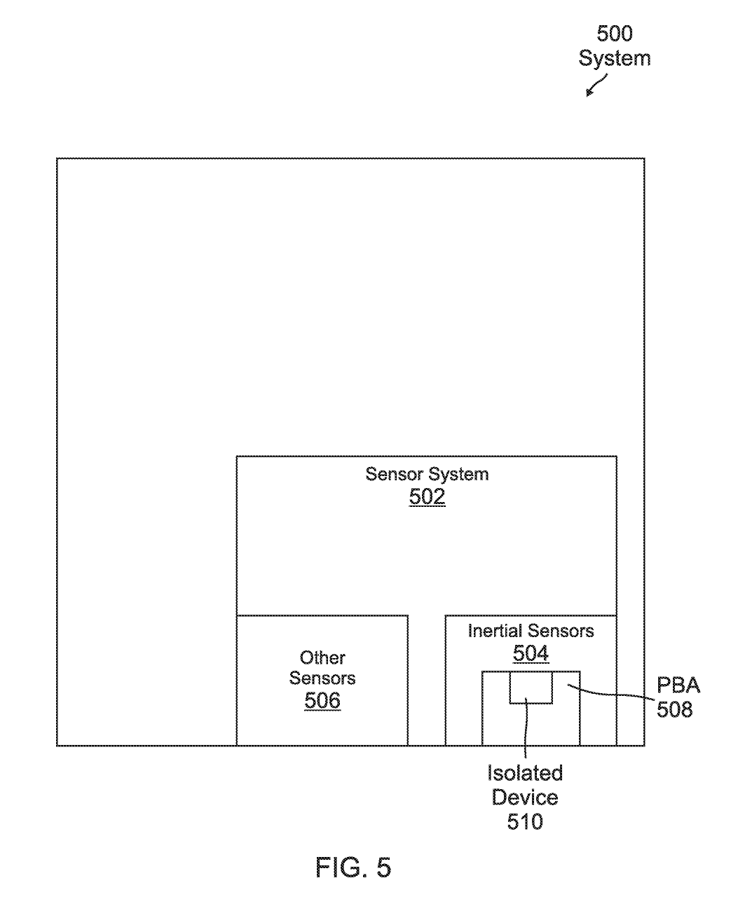

FIG. 4 illustrates a method 400, which can be utilized to implement one example embodiment of the present invention. For example, the method 400 can be utilized to implement the exemplary devices 100a-100d illustrated in FIGS. 1A-1D. As such, referring to FIGS. 1A-1D and 4, the method 400 begins by providing or forming an electronic component on a PBA (402). For this example embodiment, the electronic component thus provided or formed is the electronic component 104a and the PBA is the PBA 102a. Next, a protective cap (or cover) is formed over the electronic component (404). For example, the protective cap is the protective cap 106b in FIG. 1B. A determination is then made about whether or not additional structural support is needed for the electronic component (406). If additional structural support is needed for the electronic component, the cavity (e.g., 108c in FIG. 1C) between the protective cap 106c and the electronic component 104c is filled with a (e.g., low elastic modulus) potting material 110d in FIG. 1D (408). The method is then terminated. However, if (406) additional structural support is not needed for the electronic component, the method is terminated.

FIG. 5 illustrates a simplified, schematic block diagram of a system 500, which can be utilized to implement one example embodiment of the present invention. For this embodiment, the system 500 illustrated in FIG. 5 is a spacecraft, such as, for example, a satellite. In a second embodiment, the system is a guided projectile, such as, for example, a large caliber projectile. Referring to FIG. 5, the exemplary system 500 includes (among other components) a sensor system 502, which is a component of a navigational and guidance subsystem for guiding a spacecraft or large caliber projectile. The sensor system 502 includes (among other components) a plurality of inertial sensors 504, and a plurality of other sensors 506 that also function to guide the spacecraft or large caliber projectile. The plurality of inertial sensors 504 includes at least one printed board assembly (PBA) 508. The PBA 508 includes (e.g., among other components) a plurality of MEMS sensors (e.g., sensors 204a, 204b, 304a, 304b in FIGS. 2A-3B) mounted onto the PBA (e.g., PBA 102a in FIG. 1A), and the PBA 508 includes an electronic component and a protective cap (e.g., 104c and 106c in FIG. 1C) that form an isolated device 510 (e.g., isolated stress-sensitive component). If warranted, the cavity formed between the electronic component and the protective cap can be filled with a (e.g., low modulus) potting material. As such, for this exemplary embodiment, the system 500 provides stress-sensitive component isolation for operations in severe environments.

### Example Embodiments

Example 1 includes a device for stress-sensitive component isolation, comprising: a circuit board assembly; a plurality of electronic components mounted onto a surface of the circuit board assembly; and a protective cap disposed over at least one electronic component of the plurality of electronic components and mounted onto the surface of the circuit board assembly.

Example 2 includes the device of Example 1, further comprising: a first potting material disposed within a cavity formed between the protective cap and the at least one electronic component of the plurality of electronic components.

Example 3 includes the device of any of Examples 1-2, further comprising: a first potting material disposed within a cavity formed between the protective cap and the at least one electronic component of the plurality of electronic components; and a second potting material disposed on the protective cap, wherein the first potting material has a first modulus of elasticity and the second potting material has a second modulus of elasticity.

Example 4 includes the device of Example 3, wherein a modulus value for the first modulus of elasticity is lower than a modulus value for the second modulus of elasticity.

Example 5 includes the device of any of Examples 3-4, wherein the protective cap is configured to isolate the at least one electronic component from the second potting material.

Example 6 includes the device of any of Examples 3-5, wherein the protective cap is configured to mitigate stress induced into the at least one electronic component by the second potting material during the life of the device.

Example 7 includes the device of any of Examples 1-6, wherein the protective cap comprises at least one of a molded plastic material or a formed metal material.

Example 8 includes the device of any of Examples 2-7, wherein the first potting material comprises a plurality of polystyrene beads.

Example 9 includes the device of any of Examples 3-8, wherein the second potting material comprises a material having a high modulus of elasticity.

Example 10 includes the device of any of Examples 3-9, wherein a coefficient of thermal expansion associated with the first potting material is substantially equal to a coefficient of thermal expansion associated with the second potting material.

Example 11 includes a method for stress-sensitive component isolation, comprising: providing an electronic component on a surface of a board assembly; forming a protective cap over the electronic component; determining if the electronic component requires structural support; and filling a cavity between the electronic component and the protective cap with a first potting material if the electronic component requires structural support.

Example 12 includes the method of Example 11, further comprising: forming a layer of a second potting material on the surface of the board assembly and the protective cap.

Example 13 includes the method of Example 12, wherein the filling comprises filling the cavity with the first potting material having a first modulus of elasticity; and the forming the layer comprises forming the layer of the second potting material with the second potting material having a second modulus of elasticity, wherein a value of the first modulus of elasticity is lower than a value of the second modulus of elasticity.

Example 14 includes the method of any of Examples 11-13, wherein the filling the cavity comprises filling the cavity with an expandable polystyrene bead foam.

Example 15 includes the method of any of Examples 12-14, wherein the forming the layer comprises forming the layer with a layer of a high modulus material.

Example 16 includes a system, comprising: a sensor system; a plurality of inertial sensors in the sensor system; a circuit board assembly in an inertial sensor of the plurality of inertial sensors; a plurality of electronic components mounted onto a surface of the circuit board assembly; and a protective cap disposed over at least one electronic component of the plurality of electronic components and mounted onto the surface of the circuit board assembly.

Example 17 includes the system of Example 16, wherein the sensor system is a subsystem of a navigational and guidance system configured to guide a vehicle during or after a launch of the vehicle.

Example 18 includes the system of any of Examples 16-17, wherein the system comprises a spacecraft.

Example 19 includes the system of any of Examples 16-18, wherein the plurality of inertial sensors comprises a plurality of MEMS inertial sensors.

Example 20 includes the system of any of Examples 16-19, wherein the sensor system is a subsystem of a guided projectile.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A device for stress-sensitive component isolation, comprising:
a circuit board assembly;
a plurality of electronic components mounted onto a surface of the circuit board assembly; and
a protective cap disposed over at least one electronic component of the plurality of electronic components and mounted onto the surface of the circuit board assembly.

2. The device of claim 1, further comprising:
a first potting material disposed within a cavity formed between the protective cap and the at least one electronic component of the plurality of electronic components.

3. The device of claim 1, further comprising:
a first potting material disposed within a cavity formed between the protective cap and the at least one electronic component of the plurality of electronic components; and
a second potting material disposed on the protective cap, wherein the first potting material has a first modulus of elasticity and the second potting material has a second modulus of elasticity.

4. The device of claim 3, wherein a modulus value for the first modulus of elasticity is lower than a modulus value for the second modulus of elasticity.

5. The device of claim 3, wherein the protective cap is configured to isolate the at least one electronic component from the second potting material.

6. The device of claim 3, wherein the protective cap is configured to mitigate stress induced into the at least one electronic component by the second potting material during the life of the device.

7. The device of claim 1, wherein the protective cap comprises at least one of a molded plastic material or a formed metal material.

8. The device of claim 2, wherein the first potting material comprises a plurality of polystyrene beads.

9. The device of claim 3, wherein the second potting material comprises a material having a high modulus of elasticity.

10. The device of claim 3, wherein a coefficient of thermal expansion associated with the first potting material is substantially equal to a coefficient of thermal expansion associated with the second potting material.

11. A method for stress-sensitive component isolation, comprising:
providing an electronic component on a surface of a board assembly;
forming a protective cap over the electronic component;
determining if the electronic component requires structural support; and
filling a cavity between the electronic component and the protective cap with a first potting material if the electronic component requires structural support.

12. The method of claim 11, further comprising:
forming a layer of a second potting material on the surface of the board assembly and the protective cap.

13. The method of claim 12, wherein the filling comprises filling the cavity with the first potting material having a first modulus of elasticity; and
the forming the layer comprises forming the layer of the second potting material with the second potting material having a second modulus of elasticity, wherein a value of the first modulus of elasticity is lower than a value of the second modulus of elasticity.

14. The method of claim 11, wherein the filling the cavity comprises filling the cavity with an expandable polystyrene bead foam.

15. The method of claim 12, wherein the forming the layer comprises forming the layer with a layer of a high modulus material.

16. A system, comprising:
a sensor system;
a plurality of inertial sensors in the sensor system;
a circuit board assembly in an inertial sensor of the plurality of inertial sensors;
a plurality of electronic components mounted onto a surface of the circuit board assembly; and
a protective cap disposed over at least one electronic component of the plurality of electronic components and mounted onto the surface of the circuit board assembly.

17. The system of claim 16, wherein the sensor system is a subsystem of a navigational and guidance system configured to guide a vehicle during or after a launch of the vehicle.

18. The system of claim 16, wherein the system comprises a spacecraft.

19. The system of claim 16, wherein the plurality of inertial sensors comprises a plurality of MEMS inertial sensors.

20. The system of claim 16, wherein the sensor system is a subsystem of a guided projectile.
